(19) United States
(12) Patent Application Publication
(10) Pub. No.: US 2013/0293226 A1
(43) Pub. Date: Nov. 7, 2013

(54) ELECTRIC CURRENT SENSOR

(71) Applicants: Ikuo ONUMA, Tokyo (JP); Yoshiyuki Watanabe, Tokyo (JP); Masahiro Saito, Tokyo (JP)

(72) Inventors: Ikuo ONUMA, Tokyo (JP); Yoshiyuki Watanabe, Tokyo (JP); Masahiro Saito, Tokyo (JP)

(73) Assignee: MITSUMI ELECTRIC CO., LTD., Tokyo (JP)

(21) Appl. No.: 13/774,068

(22) Filed: Feb. 22, 2013

(30) Foreign Application Priority Data
May 1, 2012 (JP) 2012-104958
Jan. 15, 2013 (JP) 2013-004289

(51) Int. Cl. G01R 33/02

(52) U.S. Cl. CPC G01R 33/02
USPC 324/253

(57) ABSTRACT

Disclosed is an electric current sensor, including a conducting wire, a core having a hole portion mating with the conducting wire and a gap communicating with the hole portion, and a magnetic sensor having a magnetic flux detection part arranged in the gap.

### BACKGROUND OF THE INVENTION

1. Field of the Invention

An aspect of the present invention relates to an electric current sensor.

2. Description of the Related Art

For example, Japanese Patent Application Publication No. 2003-014789 has been known as a related art document in regard to an electric current sensor including a conducting wire and a core.

For example, as precision in a positional relationship between a conducting wire and a core is improved, a dispersion of an electric characteristic between individual electric current sensors may be suppressed. However, it may be difficult in the related art to determine a positional relationship between a conducting wire and a core with increased precision.

### SUMMARY OF THE INVENTION

According to one aspect of the present invention, there is provided an electric current sensor, including a conducting wire, a core having a hole portion mating with the conducting wire and a gap communicating with the hole portion, and a magnetic sensor having a magnetic flux detection part arranged in the gap.

### BRIEF DESCRIPTION OF THE DRAWINGS

FIG. 1 is a perspective view of an electric current sensor according to one embodiment of the present invention.

FIG. 2 is a perspective view of an electric current sensor according to one embodiment of the present invention.

FIG. 3 is an exploded perspective view of an electric current sensor according to one embodiment of the present invention.

FIG. 4 is a diagram illustrating a process for assembling a conducting wire and a core.

FIG. 5 is a diagram illustrating a process for assembling a conducting wire and a core.

FIG. 6A, FIG. 6B, FIG. 6C, FIG. 6D, and FIG. 6E are a set providing a full view of a sensor holder.

FIG. 7 is a perspective view of a sub-assembly constituting an electric current sensor.

FIG. 8 is a front view of a sub-assembly.

FIG. 9 is a cross-sectional view thereof along A-A of FIG. 8.

FIG. 10A, FIG. 10B, and FIG. 100 are diagrams illustrating a relationship between a conducting wire and a core when simulation is executed.

FIG. 11 is a result of simulation for magnetic flux density at a center of a gap in a direction of a Z-axis.

FIG. 12 is a graph illustrating linearity of a measured output voltage of a magnetic sensor in a case where a core formed in such a manner that a longitudinal direction thereof coincides with an easy direction of magnetization of an oriented magnetic steel sheet is used.

FIG. 13 is a graph illustrating linearity of a measured output voltage of a magnetic sensor in a case where a core formed in such a manner that a longitudinal direction thereof does not coincide with an easy direction of magnetization of an oriented magnetic steel sheet is used.

FIG. 14 is a graph illustrating linearity of a measured output voltage of a magnetic sensor in a case where a core formed from a non-oriented magnetic steel sheet is used.

FIG. 15 is a diagram illustrating one example of mating of a core with a conducting wire.

FIG. 16 is a diagram illustrating one example of mating of a core with a conducting wire.

FIG. 17 is a table illustrating one example of arrangement of terminals of an electric current sensor.

FIG. 18 is a table illustrating one example of arrangement of terminals of an electric current sensor.

FIG. 19 is a perspective view of an electric current sensor according to one embodiment of the present invention.

FIG. 20 is a perspective view of an electric current sensor whose cover has been removed.

FIG. 21A and FIG. 21B are perspective views of a sensor holder.

FIG. 22A, FIG. 22B, FIG. 22C, FIG. 22D, and FIG. 22E are a set providing a full view of a sensor holder.

### DETAILED DESCRIPTION OF THE PREFERRED EMBODIMENTS

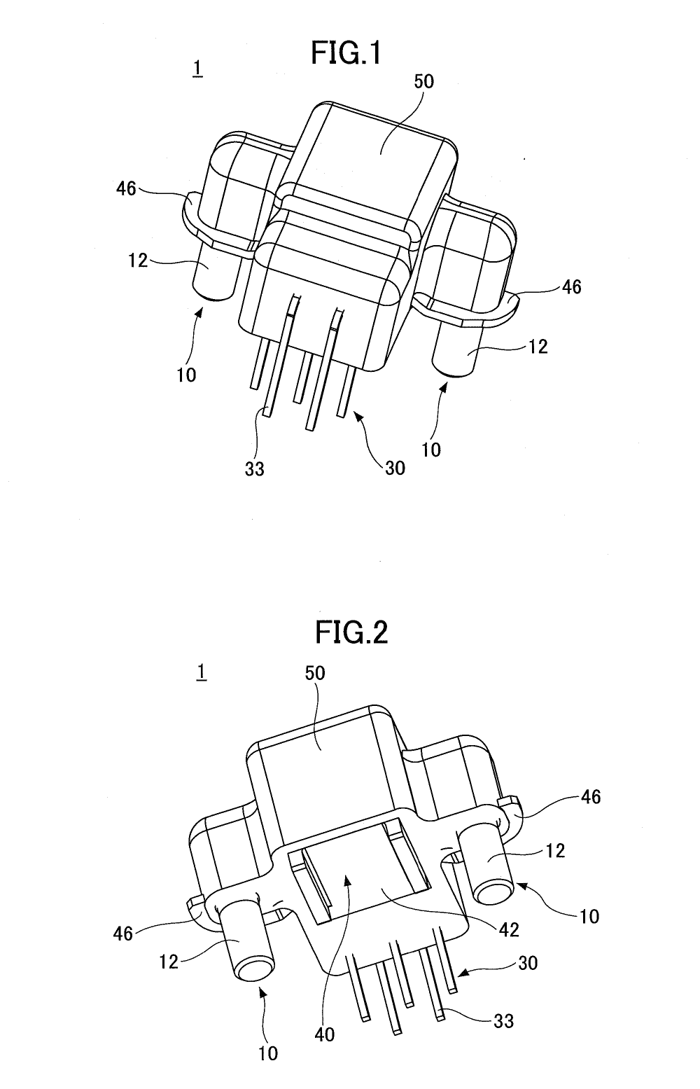

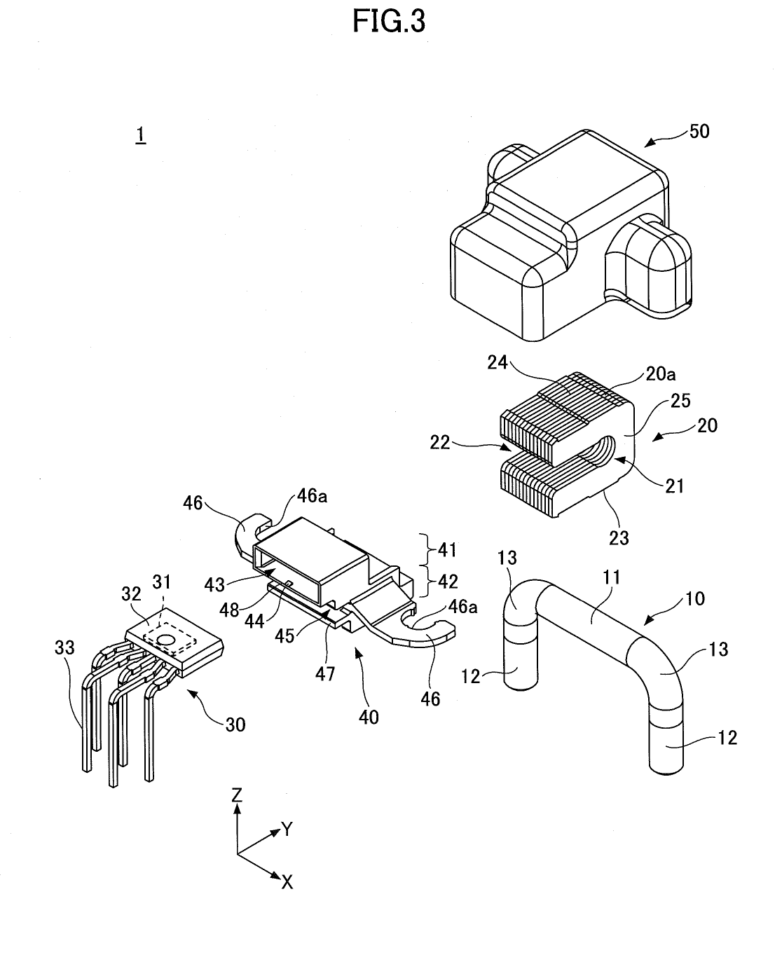

FIG. 1 is a top perspective view of an electric current sensor 1 according to one embodiment of the present invention. FIG. 2 is a bottom perspective view of the electric current sensor 1. FIG. 3 is an exploded perspective view of the electric current sensor 1. The electric current sensor 1 is a device for detecting a magnetic flux (magnetic field) generated by an electric current passing through a conducting wire 10 and outputting a detection signal in response to a change in such a detected magnetic flux (magnetic field). It is possible to use a detection signal outputted from the electric current sensor 1 to measure a value of an electric current passing through the conducting wire 10. The electric current sensor 1 includes, for example, the conducting wire 10, a core 20, a magnetic sensor 30, a sensor holder 40, and a cover 50.

The core 20 collects magnetic flux generated by an electric current passing through the conducting wire 10 and forms a path through which such magnetic flux passes. The core 20 has a circular hole portion 21 mating with the conducting wire 10 and a gap 22 communicating with the circular hole portion 21. The magnetic sensor 30 has a magnetic flux detection part 32 arranged in the gap 22 and a lead part 33 for outputting a detection signal externally in response to magnetic flux detected by the magnetic flux detection part 32. The sensor holder 40 is a supporting member for supporting the magnetic flux detection part 32 of the magnetic sensor 30. The cover 50 is a cover part for covering the core 20.

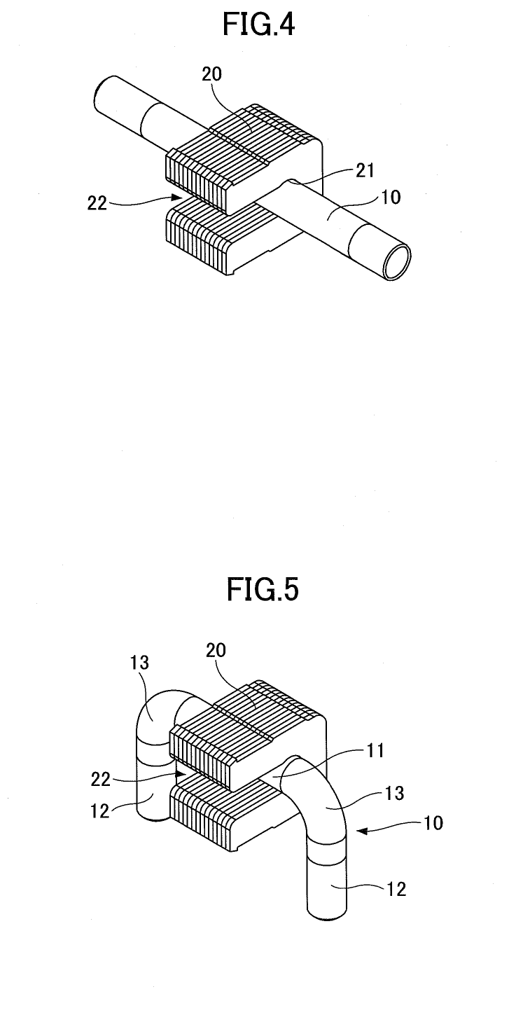

FIG. 4 and FIG. 5 are diagrams illustrating a process for assembling the conducting wire 10 and the circular hole portion 21 of the core 20. The conducting wire 10 is a linear rod before being assembled in the circular hole portion 21. As illustrated in FIG. 4, the linear conducting wire 10 is inserted into the circular hole portion 21 in a direction of an axis line passing through a center of a circular hole in the circular hole portion 21.

The conducting wire 10 and the circular hole portion 21 are molded to have a mating relationship, and hence, it is possible to insert the conducting wire 10 into the circular hole portion 21 to readily determine a positional relationship between the conducting wire 10 and the core 20 with increased precision in accordance with a predetermined dimension. Furthermore, the conducting wire 10 and the circular hole portion 21 have a mating relationship, and hence, it is possible to prevent the conducting wire 10 from moving in a direction of the communication in the gap 22 and separating from the core 20, although the circular hole portion 21 communicates with the gap 22.

Furthermore, the conducting wire 10 and the circular hole portion 21 have a mating relationship, and hence, it is possible to readily attain miniaturization and cost reduction of an electric current sensor as compared to a configuration in which a core is simply arranged to be spaced around a conducting wire. Furthermore, a larger gap is thus not present, and hence, it is possible to improve magnetic sensitivity (magnetic field strength in a gap per unit electric current passing through a conducting wire) of a magnetic sensor to reduce externally induced noise. Furthermore, it is possible to suppress a dispersion of an electrical characteristic such as the magnetic sensitivity between electric current sensors. Furthermore, an electrical conductor generally closely contacts a core, and hence, it is possible to release heat of an electrical conductor via a core efficiently. A heat release property is thus better, and hence, it is possible to suppress a temperature rise of an entire electric current sensor even if a larger amount of electric current passes through an electric conductor.

Next, as illustrated in FIG. 5, an insertion part 11 of the conducting wire 10 mates with the circular hole portion 21, and subsequently, bended at sites that do not mate with the circular hole portion 21. Thus, the conducting wire 10 is bent at both sides of the core 20 in a direction of an axis line of the circular hole portion 21, and thereby, bending parts 13 are formed between the insertion part 11 and end parts 12. The insertion part 11 is a linear part including a mating site of the conducting wire 10 with the circular hole portion 21. It is possible to attach the electric current sensor 1 to an attachment member that is not illustrated in the figure, at the end parts 12.

Additionally, it is preferable for a method for mating the conducting wire 10 with the circular hole portion 21 to be a running fit (wherein a maximum limit of size of an outer diameter of the conducting wire 10 is less than a minimum limit of size of an inner diameter of the circular hole portion 21) so that an electrical characteristic of the electric current sensor 1 is not changed by mating stress.

Next, each component of the electric current sensor 1 will be described in more detail.

As illustrated in FIG. 3, the conducting wire 10 is an electric conductor that has a circular cross-section capable of mating with the circular hole portion 21 and a constant wire diameter. Furthermore, it is preferable to interpose an insulator between the conducting wire 10 and the circular hole portion 21 so that an electric current passing through the conducting wire 10 does not leak to the core 20. Such an insulator may be a coating of the conducting wire 10, a coating of the core 20, or an insulating member arranged between the conducting wire 10 and the circular hole portion 21. For a specific example of the conducting wire 10, an enamel-coated copper wire is provided. Furthermore, for a specific example of an insulating layer such as an insulating coating, there is provided an enamel coating, a polyurethane coating, a polyimide coating, a polyamide-imide coating, etc.

It is preferable for the conducting wire 10 to mate with the circular hole portion 21 via rotatable mating with respect to the core 20. Thereby, it is possible to orient the end parts 12 to an arbitrary direction depending on a direction of an attachment or mounting surface of a member (for example, a substrate, etc.) to which the end parts 12 of the conducting wire 10 are attached. In the present embodiment, the conducting wire 10 has a circular cross section capable of mating with the circular hole portion 21, and hence, it is possible for the conducting wire 10 to rotate while being centered at an axis line of the circular hole portion 21 of the core 20. Furthermore, even when positions of the bending parts 13 (for example, a distance between the bending parts 13) are changed, it is possible to mount the electric current sensor 1 on a member having a variety of attachment or mounting surfaces at the end parts 12.

The core 20 is a path for magnetic flux on which the gap 22 is formed in the middle thereof, and is a soft magnetic material having a U-shaped site arranged around the insertion part 11 of the conducting wire 10. The gap 22 is a site at which a portion of the core 20 is spatially opened, and spatially communicates with the circular hole portion 21. The core 20 has a pair of extending parts 23 and 24 opposed to form the gap 22 and the circular hole portion 21, and a joining part 25 for joining the extending part 23 and the extending part 24 to form the gap 22 and the circular hole portion 21.

The core 20 has a configuration in which plural sheets 20a with identical forms are laminated by close contacting thereof. The sheets 20a are manufactured by, for example, punching a magnetic steel sheet. The sheets 20a may be mutually bonded by an adhesive or may not be bonded. When mutual bonding thereof is not conducted, it is preferable for the plural sheets 20a to be fixed by the sensor holder 40, etc., to keep a shape of the core 20, although the details thereof will be described below.

The magnetic sensor 30 has the magnetic flux detection part 32 with a rectangular parallelepiped shape and the lead parts 33 extending from one side face of the magnetic flux detection part 32. The magnetic flux detection part 32 has an electromagnetic conversion part 31 for detecting a magnetic flux density (magnetic field strength) penetrating through the gap 22 in a direction of a gap length of the gap 22 and outputting a voltage corresponding to such a detected magnetic flux density (magnetic field strength). A direction of the gap length of the gap 22 is a direction of a Z-axis which is orthogonal to a direction of an X-axis parallel to an axis line of the circular hole portion 21 and orthogonal to a direction of a Y-axis parallel to a direction of communication between the circular hole portion 21 and the gap 22.

The electromagnetic conversion part 31 is, for example, embedded in the magnetic flux detection part 32 and covered with an insulator such as a molded resin. For a specific example of the electromagnetic conversion part 31, a Hall element that utilizes Hall effect is provided. An output voltage of the electromagnetic conversion part 31 is supplied to the exterior via an attachment member such as a substrate to which the lead part 33 is attached, which is not illustrated in the figure. Furthermore, a control electric current for outputting a voltage from the electromagnetic conversion part 31 is supplied from the exterior via the lead part 33 to the electromagnetic conversion part 31.

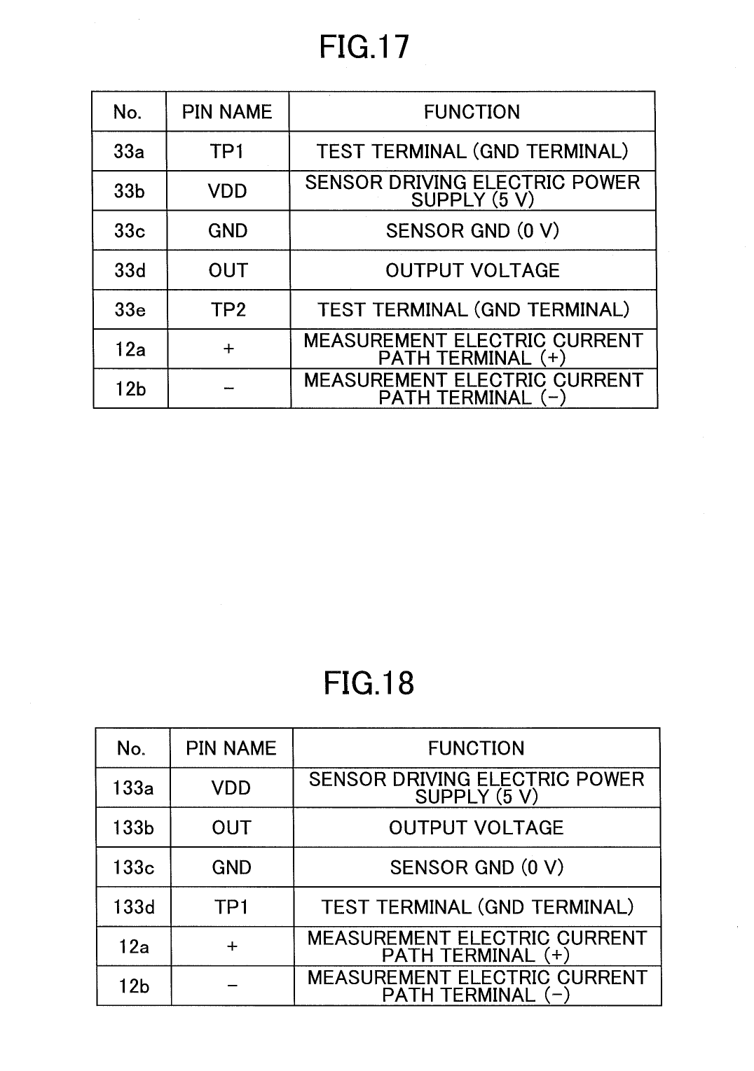

FIG. 17 is a table illustrating one example of arrangement of terminals of the electric current sensor 1. Reference numerals 33a-33e denote respective lead terminals constituting the lead parts 33 (see FIG. 8) and reference numerals 12a and 12b denote measurement electric current path terminals on the end parts 12 of the conducting wire 10 (see FIG. 8). An electric power supply voltage applied between a sensor driving electric power supply terminal 33b and a sensor ground terminal 33c is a working voltage of the electromagnetic conversion part 31. An output voltage of the electromagnetic conversion part 31 is outputted from an output voltage terminal 33d, depending on a value of an electric current passing between a measurement electric current path terminal 12a on one of the end parts 12 and a measurement electric current path terminal 12b on another of the end parts 12. Test terminals 33a and 33e are terminals to be used for checking the electromagnetic conversion part 31.

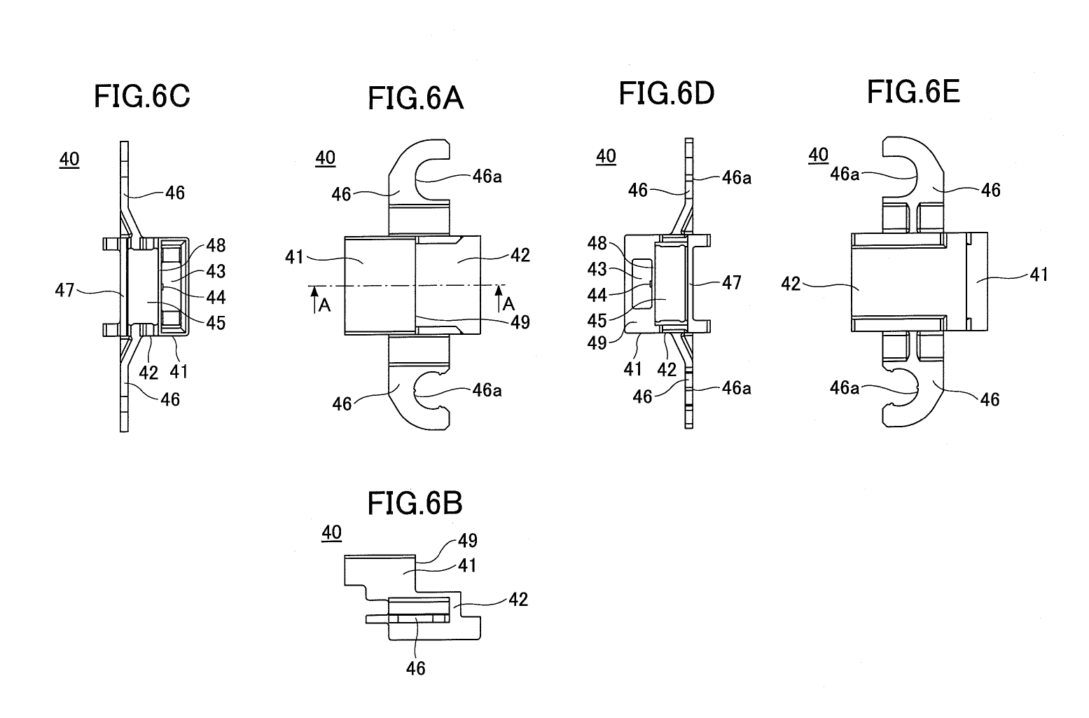

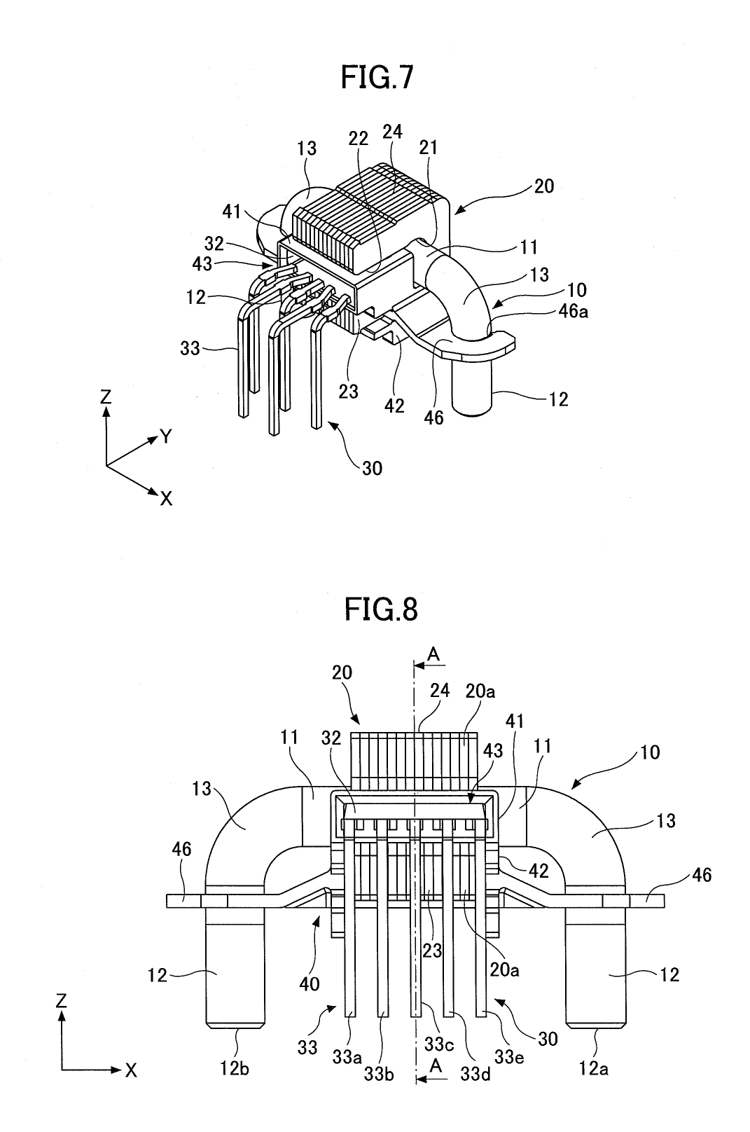

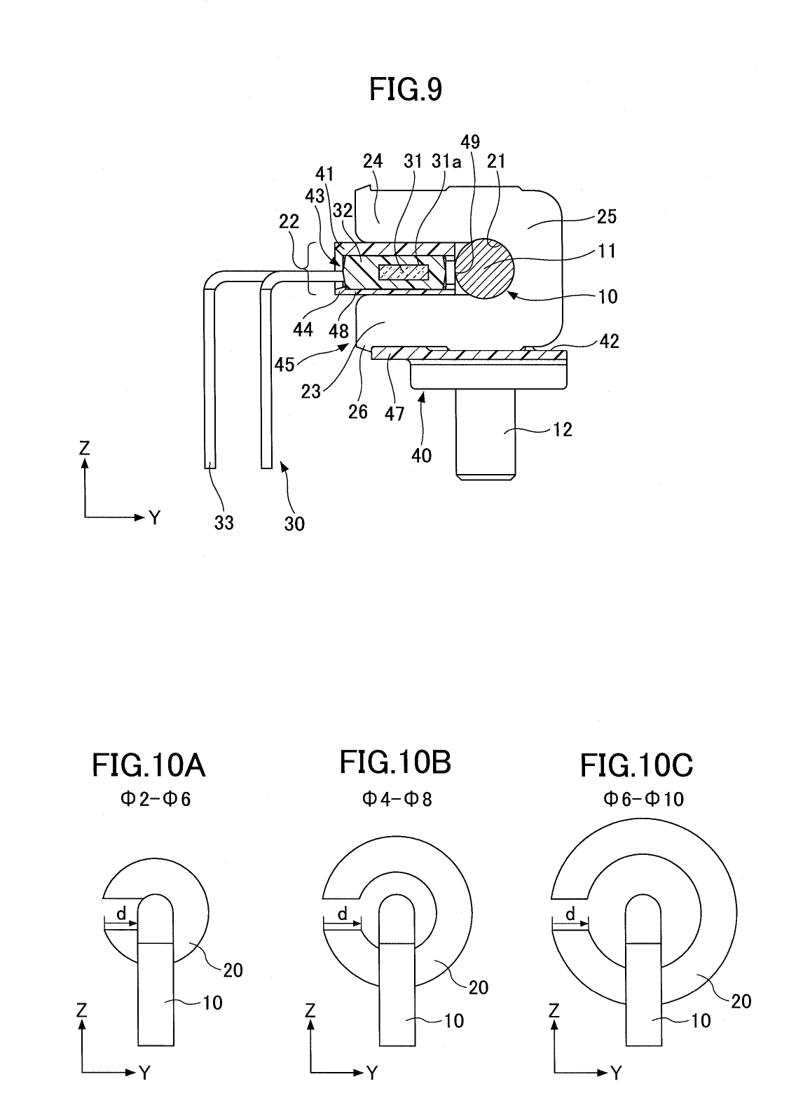

The sensor holder 40 is a resinous component for holding the magnetic flux detection part 32 in such a manner that the magnetic flux detection part 32 does not move in the gap 22. The set of FIG. 6A, FIG. 6B, FIG. 6C, FIG. 6D, and FIG. 6E provides a full view of the sensor holder 40. FIG. 6A, FIG. 6B, FIG. 6C, FIG. 6D, and FIG. 6E are a plan view of the sensor holder 40, one side view of the sensor holder 40, a front view of the sensor holder 40, a back view of the sensor holder 40, and a bottom view of the sensor holder 40, respectively. A side view at an opposite side with respect to the side view of FIG. 6B is similar to FIG. 6B, and hence, is omitted. FIG. 7 is a perspective view of a sub-assembly in which the sensor holder 40 for holding the magnetic sensor 30 and a mated piece of the conducting wire 10 and the core 20 (see FIG. 5) are assembled. FIG. 8 is a front view of the sub-assembly in FIG. 7 and FIG. 9 is a cross-sectional diagram thereof in A-A of FIG. 8.

The magnetic sensor 30 is assembled with, for example, the sensor holder 40 attached to a mated piece (core assembly) of the conducting wire 10 and the core 20 as illustrated in FIG. 5. The sensor holder 40 to which the magnetic sensor 30 has preliminarily been attached may be assembled with the core assembly. The sub-assembly (holder assembly) in FIG. 7 may temporarily be fixed by any combination of parts among the conducting wire 10, the core 20, the magnetic sensor 30, and the sensor holder 40, before being covered by the cover 50 as illustrated in FIG. 3. For example, an adhesive such as an epoxy resin is applied thereto and heat-cured.

As illustrated in FIG. 3, FIG. 6A, FIG. 6B, FIG. 6C, FIG. 6D, FIG. 6E, FIG. 7, FIG. 8, and FIG. 9, the sensor holder 40 has a sensor supporting part 41 for supporting the magnetic flux detection part 32 of the magnetic sensor 30, a conducting wire supporting part 46 for supporting the conducting wire 10, and a core supporting part 42 for pressing the extending part 23 and thereby supporting the core 20. The sensor supporting part 41 also functions as a conducting wire supporting part for supporting the conducting wire 10, although the details thereof will be described below. Thus, the sensor holder 40 has a supporting mechanism in which respective supporting parts of the magnetic flux detection part 32, the conducting wire 10, and the core 20 are integrated. It is possible to use the sensor holder 40 having such an integrated supporting mechanism to readily determine a positional relationship among the conducting wire 10, the core 20, and the magnetic flux detection part 32 with increased precision. Furthermore, it is possible to readily miniaturize the electric current sensor 1.

The sensor supporting part 41 and the core supporting part 42 are arranged in upward and downward directions parallel to a direction of a gap length of the gap 22 and the sensor supporting part 41 arranged at an upper stage and the core supporting part 42 arranged at a lower stage are partitioned by a partition wall 48. The conducting wire supporting part 46 extends outward in a direction of an X-axis from a side face of the core supporting part 42.

The sensor supporting part 41 is a site to be inserted into and arranged in the gap 22 and has a holding part for magnetic flux detection part 43 (which will also be referred to simply as a “holding part 43” below) for holding the magnetic flux detection part 32. The holding part 43 is a box-shaped site for covering and holding the magnetic flux detection part 32. The magnetic flux detection part 32 is held by the holding part 43, and thereby, the magnetic flux detection part 32 is fixed in the gap 22. The holding part 43 has an aperture portion with an opening in a direction of a Y-axis and the magnetic flux detection part 32 is inserted through such an aperture portion.

The partition wall 48 that is a peripheral wall of the holding part 43 at a side of the core supporting part 42 has an elastic claw part 44 for hanging on a side face of the magnetic flux detection part 32 at a side of the lead part 33 to lock the magnetic flux detection part 32 (see FIG. 3, FIG. 6A, FIG. 6B, FIG. 6C, FIG. 6D, FIG. 6E, and FIG. 9). The claw part 44 functions as a snap-fit part formed in such a manner that the magnetic flux detection part 32 is pressed into and held in the holding part 43. Due to the claw part 44, it is possible to fix the magnetic flux detection part 32 in the holding part 43 tightly and it is possible to prevent the magnetic flux detection part 32 from readily separating from the holding part 43. Furthermore, an assembling property and productivity are improved. The claw part 44 may be formed on a peripheral wall constituting the holding part 43 other than the partition wall 48.

Furthermore, the sensor supporting part 41 also functions as a conducting wire supporting part for supporting the conducting wire 10 and has a mating site supporting part for supporting a mating site (for example, the insertion part 11) of the conducting wire 10 with the circular hole portion 21. For example, as illustrated in FIG. 6A, FIG. 6B, FIG. 6C, FIG. 6D, and FIG. 6E, the sensor supporting part 41 has a contacting side face 49 as a mating site supporting part. For example, as illustrated in FIG. 9, the sensor supporting part 41 has the contacting side face 49 for pressing the insertion part 11 of the conducting wire 10 toward an inner peripheral surface of the circular hole portion 21 in a direction of a Y-axis orthogonal to a direction of an axis line of the circular hole portion 21 and a direction of a gap length of the gap 22, to support the conducting wire 10. It is possible for the contacting side face 49 to contact and press the insertion part 11 to readily determine a positional relationship between the conducting wire 10 and the core 20 with increased precision.

As illustrated in FIG. 3, FIG. 6A, FIG. 6B, FIG. 6C, FIG. 6D, FIG. 6E, FIG. 7, and FIG. 8, the conducting wire supporting part 46 is a non-mating site supporting part for supporting a non-mating site (for example, the end part 12) which is a site that does not mate with the circular hole portion 21 of the conducting wire 10. Such a non-mating site is a site at which the conducting wire 10 does not mate with the circular hole portion 21. The conducting wire supporting part 46 has a U-shaped arm part 46a for supporting the end part 12 of the conducting wire 10 in a direction of a Y-axis. Due to the arm part 46a, it is possible to readily determine a positional relationship between the conducting wire 10 and the core 20 with increased precision. Furthermore, the arm part 46a and the end part 12 have a mating relationship, and thereby, it is possible to fix the end part 12 tightly and improve productivity and an assembling property. Furthermore, even when the conducting wire 10 mates with the circular hole portion 21 rotatably while being centered at the circular hole portion 21, it is possible for the arm part 46 to suppress movement of the end part 12 in one direction among directions of a Y-axis.

As illustrated in FIG. 3, FIG. 6A, FIG. 6B, FIG. 6C, FIG. 6D, FIG. 6E, FIG. 7, FIG. 8, and FIG. 9, the core supporting part 42 has a holding part for extending part 45 (which will also be referred to simply as a “holding part 45” below) for holding the extending part 23 of the core 20. The holding part 45 is a box-shaped site for covering and holding the extending part 23. The extending part 23 is held by the holding part 45, and thereby, the sensor holder 40 and the core 20 are assembled together. The holding part 45 has an aperture portion with an opening in a direction of a Y-axis and the extending part 23 is inserted through such an aperture portion. That is, as the sensor holder 40 and the core 20 are assembled together, the sensor supporting part 41 is inserted into the gap 22 while the extending part 23 is inserted into the holding part 45 of the core supporting part 42.

Furthermore, as illustrated in FIG. 9, a claw part 26 for hanging on a corner portion of a peripheral wall 47 of the holding part 45 at a side opposite to a side of the gap 22 may be formed at a corner portion of the extending part 23 at a side opposite to a side of the gap 22 in a direction of a gap length of the gap 22. Due to the claw part 26, it is possible to fix the extending part 23 tightly after completion of insertion thereof into the holding part 45, and it is possible to prevent the extending part 23 from readily separating from the holding part 45. Furthermore, an assembling property and productivity are improved. The claw part 26 may be formed at another site of the extending part 23.

Furthermore, in a case where the core 20 is a lamination-type core configured by laminating the plural sheets 20a, it is possible to hold the extending part 23 in the holding part 45 to keep a shape of the core 20 steadily. In particular, in a case of a configuration provided by laminating the plural sheets 20a without mutual bonding thereof by an adhesive, etc., it is possible to keep a shape of the core 20 steadily so that the sheets 20a are not disassembled.

As illustrated in FIG. 1, FIG. 2, and FIG. 3, the cover 50 is an insulating cover part for covering the insertion part 11 and bending part 13 of the conducting wire 10, the core 20, and the sensor supporting part 41 and sensor supporting part 42 of the sensor holder 40. For a material of the cover 50, there is provided a resinous material. Thereby, for example, the core 20 contacts an external conductor that is not illustrated in the figures, and thereby, it is possible to prevent an electrical characteristic of the electric current sensor 1 from changing. Furthermore, the cover 50 may be a sealing resin formed by powder coating. Due to a minute mating clearance between the conducting wire 10 and the circular hole portion 21 or powder coating penetrating into a gap between the sensor supporting part 41 and the conducting wire 10, etc., it is possible to readily determine a positional relationship between the conducting wire 10 and the core 20 with increased precision.

Additionally, a process for bending the lead part 33 may be conducted before the cover 50 is provided or after the cover 50 is provided.

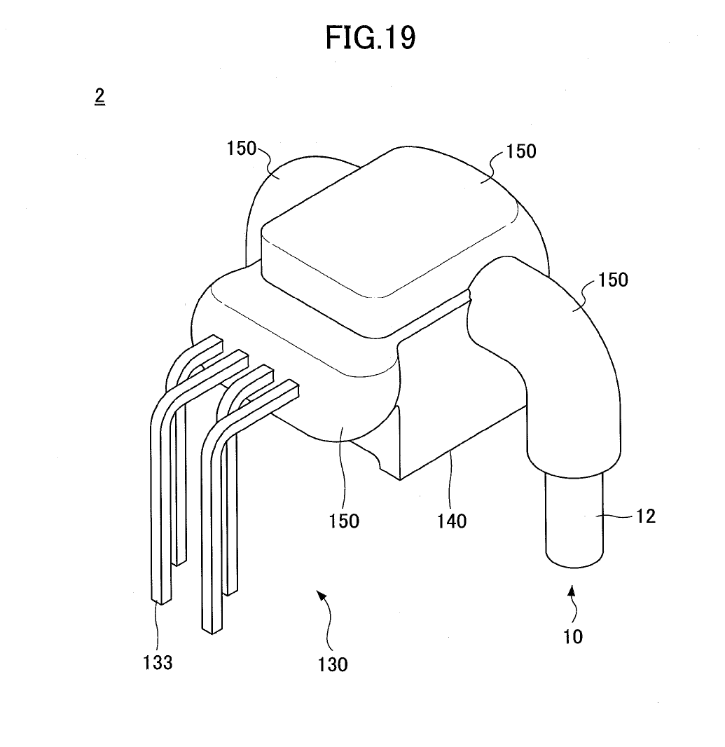

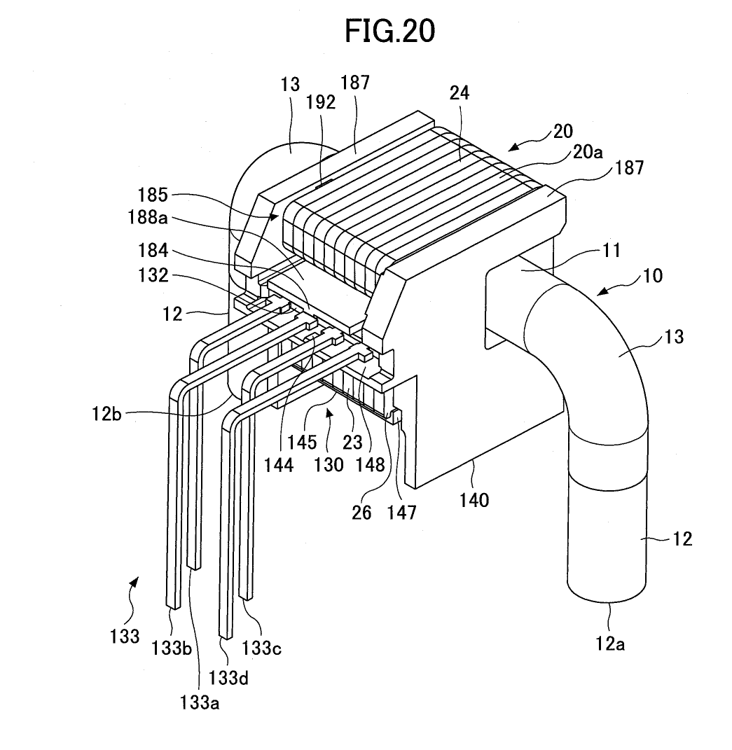

FIG. 19 is a top perspective view of an electric current sensor 2 according to one embodiment of the present invention. FIG. 20 is a top perspective view of the electric current sensor 2 in which a cover 150 has been removed. The electric current sensor 2 includes, for example, a conducting wire 10, a core 20, a magnetic sensor 130, a sensor holder 140, and the cover 150. A description(s) for a configuration and effect similar to those of the above-mentioned embodiment will be omitted or simplified.

The core 20 having a circular hole portion 21 as a hole portion mating with the conducting wire 10 and a gap 22 as a gap communicating with the hole portion 21 mating with the conducting wire 10 is similar to that of the above-mentioned embodiment. Furthermore, the cover 150 is an insulating cover part for covering at least the core 20 and is similar to the cover 50 as mentioned above.

The magnetic sensor 130 has a rectangular parallelepiped-shaped magnetic flux detection part 132 arranged in the gap 22 and a lead part 133 extending from one side face of the magnetic flux detection part 132. The magnetic flux detection part 132 has an electromagnetic conversion part for detecting a magnetic flux density (magnetic field strength) penetrating through the gap 22 in a direction of a gap length of the gap 22 and outputting a voltage corresponding to such a detected magnetic flux density (magnetic field strength). Additionally, the magnetic sensor 130 may be the magnetic sensor 30 as mentioned above or may be another-detection-type magnetic sensor.

FIG. 18 is a table illustrating one example of terminal arrangement of the electric current sensor 2.

Reference numerals 133a- 133d denote respective lead terminals constituting the lead parts 133 (see FIG. 20) and reference numerals 12a and 12b denote measurement electric current path terminals on the end parts 12 of the conducting wire 10 (see FIG. 20). An electric power supply voltage applied between a sensor driving electric power supply terminal 133b and a sensor ground terminal 133c is a working voltage of an electromagnetic conversion part of the magnetic flux detection part 132. An output voltage of the electromagnetic conversion part is outputted from an output voltage terminal 133b, depending on a value of electric current passing between a measurement electric current path terminal 12a on one end part 12 and a measurement electric current path terminal 12b on another end part 12. A test terminal 133d is a terminal to be used for checking an electromagnetic conversion part.

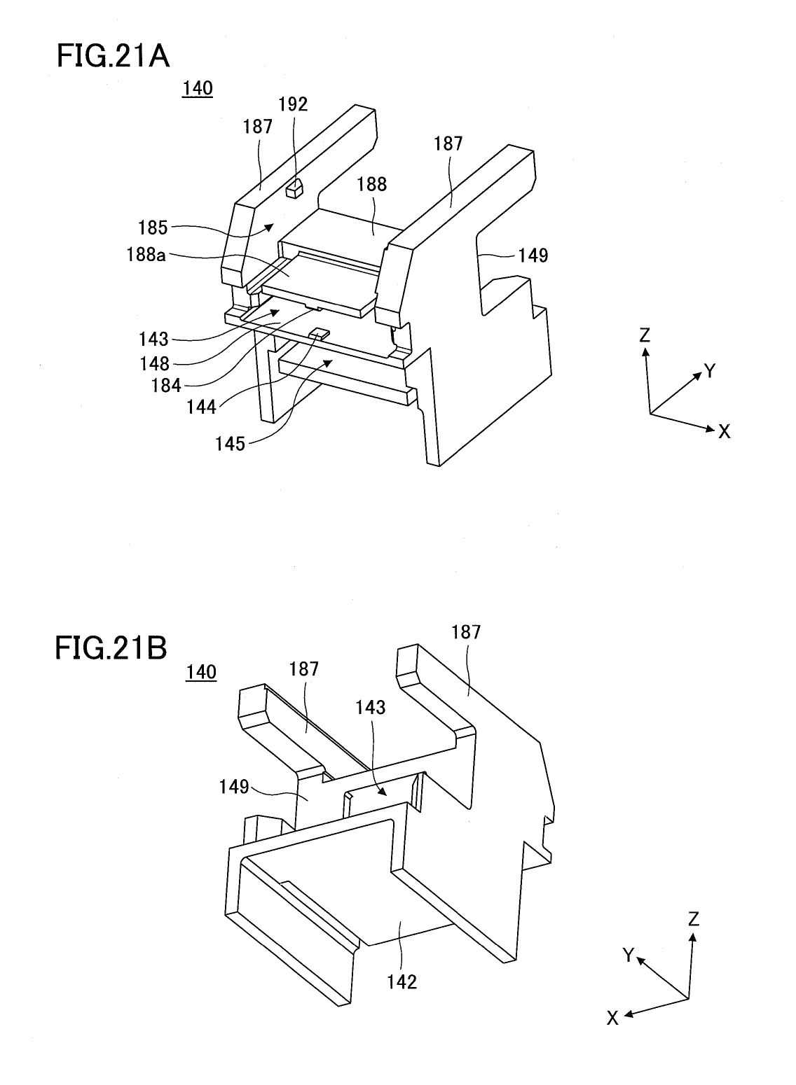

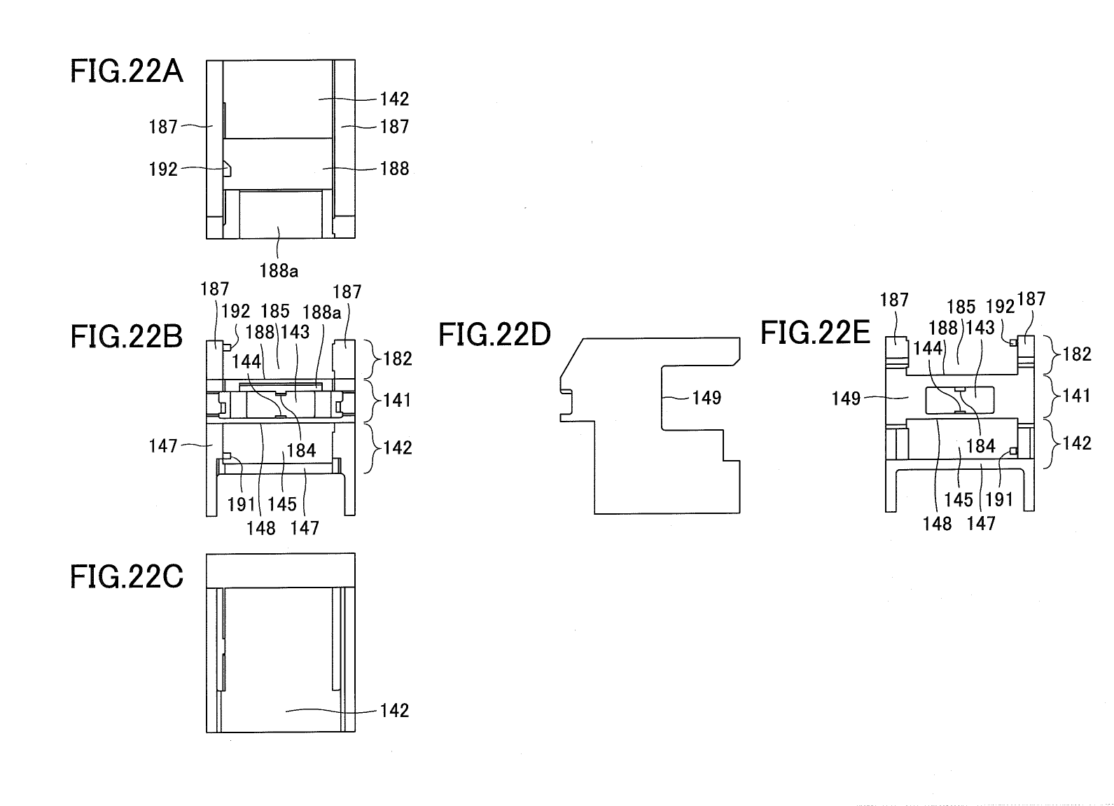

The sensor holder 140 is a resinous component for holding the magnetic flux detection part 132 in such a manner that the magnetic flux detection part 132 does not move in the gap 22. The set of FIG. 21A and FIG. 21B provides a perspective view of the sensor holder 140. FIG. 21A is a top perspective view of the sensor holder 140 and FIG. 21B is a bottom perspective view of the senor holder 140. The set of FIG. 22A, FIG. 22B, FIG. 22C, FIG. 22D, and FIG. 22E provides a full view of the sensor holder 140, wherein FIG. 22A, FIG. 22B, FIG. 22C, FIG. 22D, and FIG. 22E are a plan view, a front view, a bottom view, a side view, and a back view thereof, respectively. A side view at an opposite side with respect to the side view of FIG. 22D is similar to FIG. 22D, and hence, is omitted.

The sensor holder 140 has a sensor supporting part 141 for supporting the magnetic flux detection part 132 of the magnetic sensor 130, a core supporting part 142 for pressing the extending part 23 and thereby supporting the core 20, and a core supporting part 182 for pressing the extending part 24 and thereby supporting the core 20. The sensor supporting part 141 also functions as a conducting wire supporting part for supporting the conducting wire 10, although the details thereof will be described below. Thus, the sensor holder 140 has a supporting mechanism in which respective supporting parts for the magnetic flux detection part 132, the conducting wire 10, and the core 20 are integrated. It is possible to use the sensor holder 140 having such an integrated supporting mechanism to readily determine a positional relationship among the conducting wire 10, the core 20, and the magnetic flux detection part 132 with increased precision. Furthermore, it is possible to readily miniaturize the electric current sensor 2.

The sensor supporting part 141, the core supporting part 142, and the core supporting part 182 are arranged in upward and downward directions parallel to a direction of a gap length of the gap 22. The sensor supporting part 141 arranged at a middle stage and the core supporting part 182 arranged at an upper stage are partitioned by a partition wall 188 and the sensor supporting part 141 arranged at the middle stage and the core supporting part 142 arranged at a lower stage are partitioned by a partition wall 148.

The sensor supporting part 141 is a site to be inserted into and arranged in the gap 22 and has a holding part for magnetic flux detection part 143 (which will also be refereed to simply as a “holding part 143” below) for holding the magnetic flux detection part 132. The holding part 143 is a box-shaped site for covering and holding the magnetic flux detection part 132. The magnetic flux detection part 132 is held by the holding part 143, and thereby, the magnetic flux detection part 132 is fixed in the gap 22. The holding part 143 has an aperture portion with an opening in a direction of a Y-axis and the magnetic flux detection part 132 is inserted through such an aperture part.

The partition wall 148 that is a peripheral wall of the holding part 143 at a side of the core supporting part 142 has an elastic claw part 144 for hanging on a side face of the magnetic flux detection part 132 at a side of the lead part 133 to lock the magnetic flux detection part 132. The claw part 144 functions as a snap-fit part formed in such a manner that the magnetic flux detection part 132 is pressed into and held in the holding part 143. Due to the claw part 144, it is possible to fix the magnetic flux detection part 132 in the holding part 143 tightly and it is possible to prevent the magnetic flux detection part 132 from readily separating from the holding part 143. Furthermore, an assembling property and productivity are improved. The claw part 144 may be formed on a peripheral wall constituting the holding part 143 other than the partition wall 148.

For example, the partition wall 188 that is a peripheral wall of the holding part 143 at a side of the core supporting part 182 has an elastic claw part 184 for hanging on a side face of the magnetic flux detection part 132 at a side of the lead part 133 to lock the magnetic flux detection part 132. The claw part 184 also has a function and effect similar to those of the claw part 144. The claw part 184 is formed on a board-shaped extending-outward part 188a that extends outward from the partition wall 188 in a direction of insertion of the magnetic flux detection part 132, to oppose the claw part 144. The extending-out part 188a is formed elastically to readily bend while the partition wall 188 is a fulcrum. The extending-outward part 188a has such an elasticity, and thereby, an assembling property of the magnetic flux detection part 132 at time of insertion thereof is improved. The claw part 184 is formed on an end part of the extending-outward part 188a in a direction of extension thereof.

Furthermore, the sensor supporting part 141 also functions as a conducting wire supporting part for supporting the conducting wire 10 and has a mating site supporting part for supporting a mating site (for example, the insertion part 11) of the conducting wire 10 with the circular hole portion 21. The sensor supporting part 141 has, for example, a contacting side face 149 as a mating site supporting part. The contacting side face 149 has a function and effect similar to those of the contacting side face 49 as described above (see FIG. 9).

The core supporting part 142 has a holding part for extending part 145 (which will also be referred to as simply a “holding part 145” below) for holding the extending part 23 of the core 20. The holding part 145 is a box-shaped site for covering and holding the extending part 23. The extending part 23 is held by the holding part 145, and thereby, the sensor holder 140 and the core 20 are assembled together. The holding part 145 has an aperture portion with an opening in a direction of a Y-axis and the extending part 23 is inserted through such an aperture portion. That is, as the sensor holder 140 and the core 20 are assembled together, the sensor supporting part 141 is inserted into the gap 22 while the extending part 23 is inserted into the holding part 145 of the core supporting part 142.

The holding part 145 has a protrusion part 191 formed to press and hold the core 20. The protrusion part 191 is provided on an inner face of a peripheral wall 147 constituting the holding part 145, and thereby, a gap between an inner face of the peripheral wall 147 and the extending part 23 increases when the extending part 23 is inserted into the holding part 145. Thereby, it is possible to improve an assembling property of the extending part 23 and the holding part 145, and it is possible for the protrusion part 191 to press the extending part 23 toward a direction of protrusion of the protrusion part 191 so that it is possible to fix the core on the sensor holder 40 tightly. The protrusion part 191 in the case of illustration in the figures protrudes from an inner face of the peripheral wall 147 of the holding part 145 in a direction of an axis line of the circular hole portion 21.

In a case where the core 20 is a lamination-type core configured by laminating the plural sheets 20a, it is possible to hold the extending part 23 in the holding part 145 to keep a shape of the core 20 steadily. In particular, in a case of a configuration provided by laminating the plural sheets 20a without mutual bonding thereof by an adhesive, etc., it is possible to keep a shape of the core 20 steadily so that the sheets 20a are not disassembled. Furthermore, a positional displacement of each arranged sheet 20a is more readily suppressed by having the protrusion part 191, and hence, a characteristic of electric current detection is stabilized.

Furthermore, as illustrated in FIG. 20, the claw part 26 for hanging on a corner portion of the peripheral wall 147 of the holding part 145 at a side opposite to a side of the gap 22 may be formed on a corner portion of the extending part 23 at a side opposite to a side of the gap 22 in a direction of a gap length of the gap 22. Due to the claw part 26, it is possible to fix the extending part 23 tightly after completing insertion thereof into the holding part 145 and it is possible to prevent the extending part 23 from readily separating from the holding part 145. Furthermore, an assembling property and productivity are improved. The claw part 26 may be formed on another site of the extending part 23.

The core supporting part 182 has a holding part for extending part 185 (which will also be referred to simply as a “holding part 185”, below) for holding the extending part 24 that is an extending part other than the extending part 23. The holding part 185 has a pair of wall parts 187 for interposing and holding the extending part 24 of the core 20 in a direction of an axis line of the circular hole portion 21 of the core 20. The wall parts 187 are provided on both ends of the holding part 185 in a direction of an axis line of the circular hole portion 21 of the core 20. The extending part 24 is interposed and held by the wall parts 187, and thereby, the sensor holder 140 and the core 20 are assembled together. As the sensor holder 140 and the core 20 are assembled together, the sensor supporting part 141 is inserted into the gap 22 while the extending part 24 is inserted into the holding part 185 of the core supporting part 182.

The holding part 185 has a protrusion part 192 formed to press and hold the core 20. The protrusion part 192 is provided on an inner face of the wall part 187 constituting the holding part 185, and thereby, a gap between an inner face of the wall part 187 and the extending part 24 increases when the extending part 24 is inserted into the holding part 185. Thereby, it is possible to improve an assembling property of the extending part 24 and the holding part 185, and it is possible for the protrusion part 192 to press the extending part 24 toward a direction of protrusion of the protrusion part 192, so that it is possible to fix the core 20 on the sensor holder 40 tightly. The protrusion part 192 in the case of illustration in the figures protrudes from an inner face of the wall part 187 of the holding part 185 in a direction of an axis line of the circular hole portion 21.

In a case where the core 20 is a lamination-type core configured by laminating the plural sheets 20a, it is possible to hold the extending part 24 in the holding part 185 to keep a shape of the core 20 steadily. In particular, in a case of a configuration provided by laminating the plural sheets 20a without mutual bonding thereof by an adhesive, etc., it is possible to keep a shape of the core 20 steadily so that the sheets 20a are not disassembled. Furthermore, a positional displacement of each arranged sheet 20a is more readily suppressed by having the protrusion part 192, and hence, a characteristic of electric current detection is stabilized.

Next, a result of simulation of an electric current sensor on a computer will be described.

In three cases of FIG. 10A, FIG. 10B, and FIG. 100, simulation was executed for the magnetic flux density generated in a gap formed on a part of a cylindrical core 20 by an identical electric current passing through a conducting wire 10. FIG. 10A illustrates a case where the core 20 has an inner diameter φ2 and an outer diameter φ6,

FIG. 10B illustrates a case where the core 20 has an inner diameter φ4 and an outer diameter φ8, and FIG. 100 illustrates a case where the core 20 has an inner diameter φ6 and an outer diameter φ10. “φ*” denotes a diameter (unit: mm). In each of the cases of FIG. 10A, FIG. 10B, and FIG. 100, a diameter of each conducting wire 10 is 2 mm. FIG. 10A illustrates a configuration in which the conducting wire mates with a circular hole portion of the core 20 and FIG. 10B and FIG. 100 illustrate configurations in which the conducting wire does not mate with a circular hole portion of the core 20.

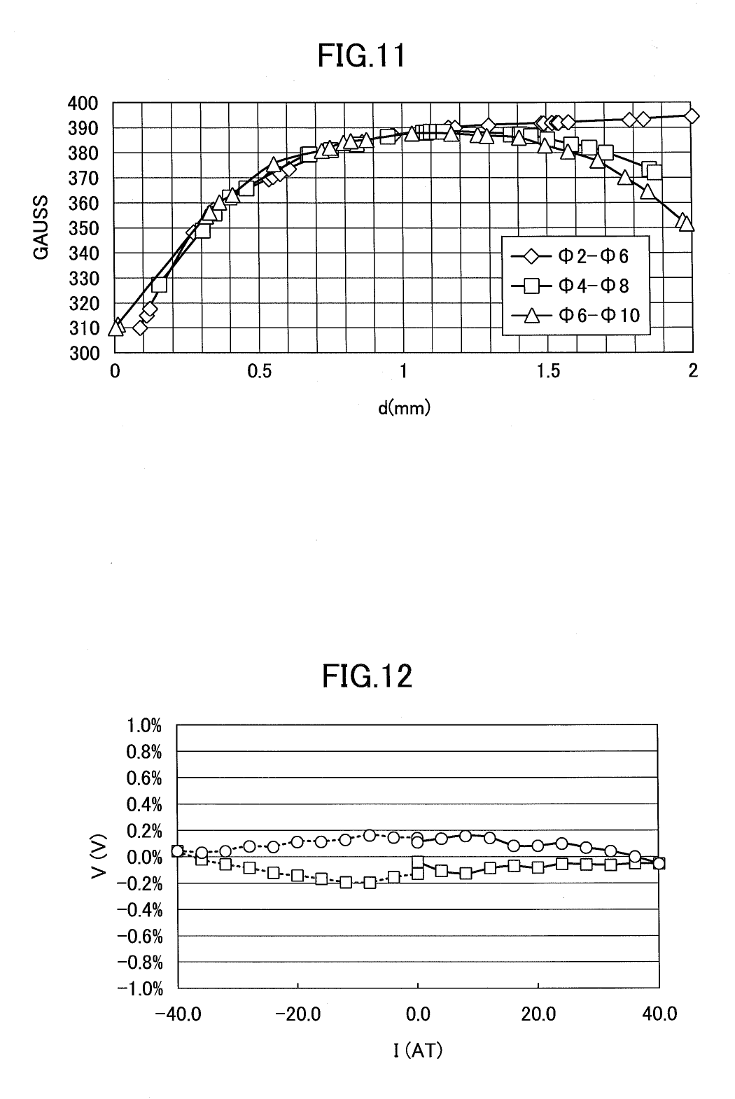

FIG. 11 illustrates a result of simulation for the magnetic flux density at a gap center in a direction of a Z-axis for the three cases of FIG. 10A, FIG. 10B, and FIG. 100. “d” denotes a length in a direction of a Y-axis at the gap center in a direction of a Z-axis, wherein an end portion of a gap at a side of an outer diameter of the core 20 is provided at 0 mm and an end portion of a gap at a side of an inner diameter of the core 20 is provided at 2 mm.

As illustrated in FIG. 11, in the cases of φ4-φ8 in FIG. 10B and φ6-φ8 in FIG. 100 in which the core 20 does not mate with the conducting wire 10, there is a space between the conducting wire 10 and the gap. Hence, when a position in the gap approaches the conducting wire 10, the magnetic flux density decreases and is not flat. A Hall element arranged in the gap outputs a signal proportional to the magnetic flux density. Therefore, when a Hall element approaches the conducting wire, it may be difficult to produce an electric current sensor that outputs a constant signal with increased precision regardless of an irregularity in a dimension between the Hall element and the conducting wire 10.

On the other hand, in the case of φ2-φ6 in FIG. 10A in which the core 20 mates with the conducting wire 10, a distribution of magnetic flux density is flatter than the other cases, when a position in the gap approaches the conducting wire 10. Therefore, when a Hall element approaches the conducting wire 10, it is possible to readily produce an electric current sensor that outputs a constant signal with increased precision regardless of an irregularity in a dimension between the Hall element and the conducting wire 10. That is, it is preferable to arrange a Hall element in the gap in such a manner that a magnetic flux detection point of the Hall element is located at a side of the conducting wire 10 mating with the circular hole portion with respect to a central position (in such a case, d=1 mm) of a gap in a direction of a Y-axis.

For example, as illustrated in FIG. 9, it is preferable for the magnetic flux detection part 32 to have a magnetic flux detection point 31a located at a side of the insertion part 11 of the conducting wire 10 mating with the circular hole portion 21 with respect to a central position of the gap 22 in a direction of a Y-axis. The magnetic flux detection point 31a is a detection reference point (magnetic field sensing point) for detecting the magnetic flux with the electromagnetic conversion part 31. Furthermore, as the magnetic flux detection point 31a is present at a side of the insertion part 11 with respect to a central position of the gap 22 in a direction of a Y-axis, it is possible to reduce an influence of externally induced noise (in particular, externally induced noise in a Y-direction). Furthermore, when the magnetic flux detection point 31a is present at a central position of the gap 22 in a Z-direction, it is also possible to reduce an influence of externally induced noise (in particular, externally induced noise in a Y direction). Hence, it is more preferable for a position of the magnetic flux detection point 31a to be provided at a central position of the gap 22 in a Z-direction and further at a side of the insertion part 11 with respect to a central position of the gap 22 in a direction of a Y-axis.

Next, a result provided by manufacturing an electric current sensor in practice and measuring an output voltage of a magnetic sensor constituting the electric current sensor will be described.

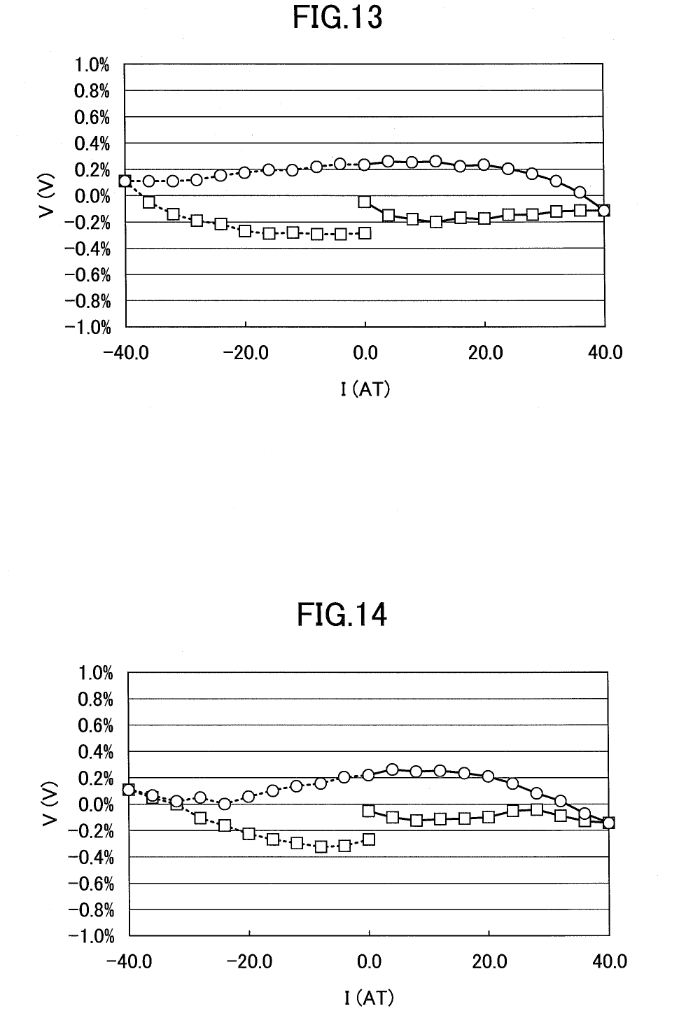

FIG. 12 and FIG: 13 are graphs of linearity of a measured output voltage of the magnetic sensor 30 in a case where the core 20 formed from an oriented magnetic steel sheet was used. FIG. 12 illustrates a case where the core 20 was used which was formed in such a manner that a direction of extension of the extending parts 23 and 24 of the core 20 (a direction of a Y-axis corresponding to a longitudinal direction of the core 20 in FIG. 9) coincided with a direction of rolling of an oriented magnetic steel sheet. On the other hand, FIG. 13 illustrates a case where the core 20 was used which was formed in such a manner that a direction of extension of a joining part 25 for joining the extending parts 23 and 24 (a direction of a Z-axis corresponding to a transverse direction of the core 20 in FIG. 9) coincided with a direction of rolling of an oriented magnetic steel sheet. Furthermore, FIG. 14 is a graph of linearity of a measured output voltage of the magnetic sensor 30 in a case where the core 20 formed from a non-oriented magnetic steel sheet was used.

In FIG. 12, FIG. 13, and FIG. 14, a horizontal axis represents an input electric current I supplied to the conducting wire 10 and a vertical axis represents a value of an error with respect to a first-order approximation line of an output voltage of the magnetic sensor 30 (output voltage=magnetic sensitivity x input electric current I+offset voltage) as expressed in percentage. In the thus defined case, when saturation and hysteresis of the core 20 increase, a difference between upper and lower data in each graph increases wherein it is illustrated that linearity of an output voltage of the magnetic sensor 30 may be reduced.

A maximum value of a difference or width between upper and lower data (hysteresis width) is 0.27% in the case of FIG. 12, 0.50% in the case of FIGS. 13, and 0.49% in the case of FIG. 14, wherein a result is obtained that the case of FIG. 12 provides the best linearity. That is, the core 20 is formed in such a manner that a longitudinal direction in which the extending parts 23 and 24 of the core 20 extend coincides with a direction of rolling of an oriented magnetic steel sheet, and thereby, it is possible to improve the linearity of the magnetic sensor 30.

Although preferred practical examples of the present invention have been described above in detail, the present invention is not limited to the above-mentioned practical examples and it is possible to apply a variety of modifications, combinations, improvements, substitutions, etc., to the above-mentioned practical examples without departing from the scope of the present invention.

For example, although a Hall element has been illustrated as a magnetic flux detection part, a magnetic flux detection part may be anisotropic (non-isotropic) magnetoresistance (AMR) element or a giant magnetoresistance (GMR) element.

Furthermore, for example, although the circular hole portion 21 mating with the conducting wire 10 has been illustrated, a hole portion other than a circular hole portion may be provided as long as such a hole portion mates with a conducting wire. For example, an elliptical hole portion or a polygonal hole portion may be provided. In such a case, it is preferable to form a shape of a conducting wire as being capable of mating with a hole portion in accordance with a shape of a hole portion.

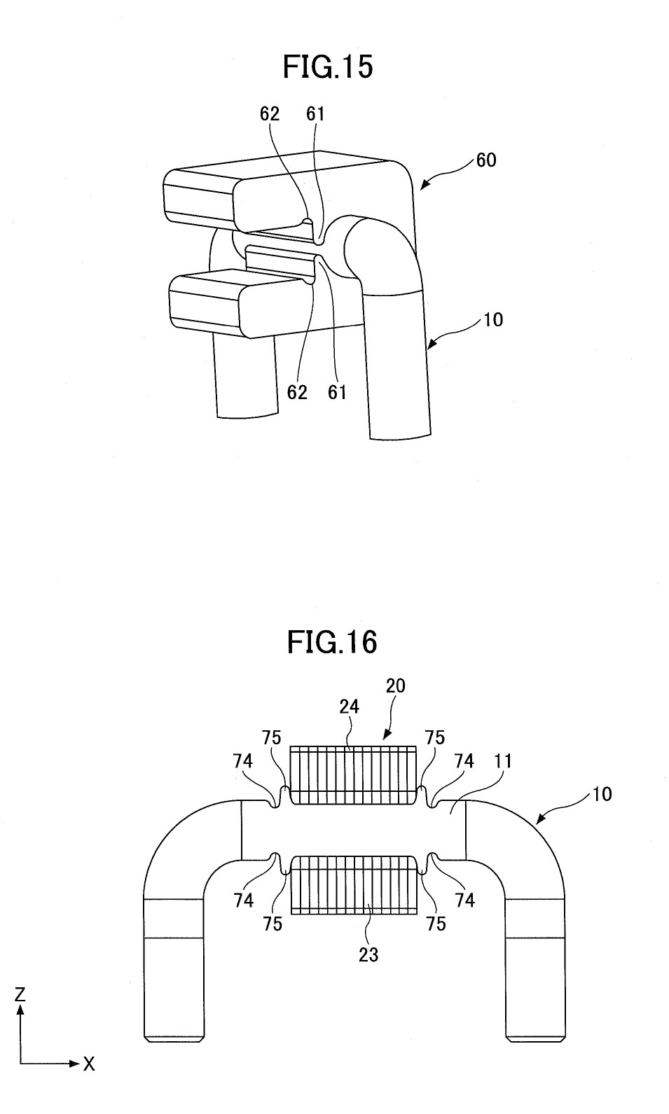

Furthermore, as illustrated in FIG. 15, a core 60 arranged around the conducting wire 10 has a protrusion part 61 between the circular hole portion and the gap. It is possible to provide the protrusion portion 61 to mate the conducting wire 10 with a circular hole portion of the core 60 even when a gap length of the gap is greater than an outer diameter of the conducting wire 10. Thereby, it is possible to readily determine a positional relationship between the conducting wire 10 and the core 60 with increased precision. Furthermore, when the protrusion 61 is formed, it is possible to cause a magnetic flux detection point of a magnetic flux detection part arranged in the gap to approach an electrical conductor, so that magnetic sensitivity is improved.

Furthermore, as illustrated in FIG. 15, the core 60 has a recess portion 62 between a circular hole portion and a gap. A sensor holder arranged in the gap hangs on the recess portion 62, and thereby, it is possible to readily position a sensor holder in the gap.

Furthermore, as illustrated in FIG. 16, the conducting wire 10 may have ridge portions 75 formed in such a manner that sites 74 at both ends of the core 20 are collapsed to swell in a direction of a diameter of the conducting wire 10. Both ends of the core 20 hang on the ridge portions 75, and thereby, it is possible to readily suppress sliding of the core 20 in a direction of insertion of the insertion part 11 of the conducting wire 10 (a direction of an X-axis).

[Appendix]

### Illustrative Embodiments of an Electric Current Sensor

At least one illustrative embodiment of the present invention may relate to an electric current sensor including a conducting wire and a core.

An object of at least one illustrative embodiment of the present invention may be to provide an electric current sensor capable of determining a positional relationship between a conducting wire and a core with increased precision more readily.

At least one illustrative embodiment of the present invention may be an electric current sensor including a conducting wire, a core having a hole portion for mating with the conducting wire and a gap communicating with the hole portion, and a magnetic sensor having a magnetic flux detection part arranged in the gap.

Illustrative Embodiment (1) is an electric current sensor including a conducting wire, a core having a hole portion mating with the conducting wire and a gap communicating with the hole portion, and a magnetic sensor having a magnetic flux detection part arranged in the gap.

Illustrative Embodiment (2) is the electric current sensor as described in Illustrative Embodiment (1), including a supporting member for supporting the magnetic flux detection part.

Illustrative Embodiment (3) is the electric current sensor as described in Illustrative Embodiment (2), wherein the supporting member has a core supporting part for supporting the core.

Illustrative Embodiment (4) is the electric current sensor as described in Illustrative Embodiment (3), wherein the core has a pair of extending parts opposed to form the gap and the core supporting part has a holding part for extending parts for holding the pair of extending parts.

Illustrative Embodiment (5) is the electric current sensor as described in Illustrative Embodiment (4), wherein the holding part for extending parts has a box part for holding one extending part of the pair of extending parts.

Illustrative Embodiment (6) is the electric current sensor as described in Illustrative Embodiment (5), wherein the holding part for extending parts has a wall part for interposing and holding an extending part other than the one extending part among the pair of extending parts.

Illustrative Embodiment (7) is the electric current sensor as described in any one of Illustrative Embodiments (4) to (6), wherein the holding part for extending parts has a protrusion part formed to press and hold the core.

Illustrative Embodiment (8) is the electric current sensor as described in any one of Illustrative Embodiments (2) to (7), wherein the supporting member has a conducting wire supporting part for supporting the conducting wire.

Illustrative Embodiment (9) is the electric current sensor as described in Illustrative Embodiment (8), wherein the conducting wire supporting part has a mating site supporting part for supporting a site of the conducting wire for mating with the hole portion.

Illustrative Embodiment (10) is the electric current sensor as described in Illustrative Embodiment (9), wherein the mating site supporting part is arranged in the gap.

Illustrative Embodiment (11) is the electric current sensor as described in Illustrative Embodiment (9) or (10), wherein the mating site supporting part has a holding part for magnetic flux detection part for holding the magnetic flux detection part.

Illustrative Embodiment (12) is the electric current sensor as described in Illustrative Embodiment (11), wherein the holding part for magnetic flux detection part has a claw part for locking the magnetic flux detection part.

Illustrative Embodiment (13) is the electric current sensor as described in any one of Illustrative Embodiments (8) to (12), wherein the conducting wire supporting part has a non-mating site supporting part for supporting a non-mating site being a site of the conducting wire for not mating with the hole portion.

Illustrative Embodiment (14) is the electric current sensor as described in Illustrative Embodiment (13), wherein the non-mating site supporting part supports the non-meting site in a direction parallel to a direction of communication between the hole portion and the gap.

Illustrative Embodiment (15) is the electric current sensor as described in any one of Illustrative Embodiments (1) to (14), wherein the core has a configuration in such a manner that plural sheets are laminated.

Illustrative Embodiment (16) is the electric current sensor as described in Illustrative Embodiment (15), wherein the plural sheets are laminated without being mutually bonded by an adhesive.

Illustrative Embodiment (17) is the electric current sensor as described in any one of Illustrative Embodiments (1) to (16), wherein the conducting wire is rotatable with respect to the core.

Illustrative Embodiment (18) is the electric current sensor as described in any one of Illustrative Embodiments (1) to (17), wherein the core is made from an oriented magnetic steel sheet.

Illustrative Embodiment (19) is the electric current sensor as described in Illustrative Embodiment (18), wherein the core has a pair of extending parts opposed to form the gap and the core is formed in such a manner that a direction of extension of the extending parts coincides with a direction of rolling of the oriented magnetic steel sheet.

Illustrative Embodiment (20) is the electric current sensor as described in any one of Illustrative Embodiments (1) to (19), including an insulating cover part for covering the core.

Illustrative Embodiment (21) is the electric current sensor as described in Illustrative Embodiment (20), wherein the cover part is made by powder coating.

Illustrative Embodiment (22) is the electric current sensor as described in any one of Illustrative Embodiments (1) to (21), wherein the magnetic flux detection part has a magnetic flux detection point located at a side of the hole portion with respect to a position of a center of the gap in a direction of communication between the hole portion and the gap.

Illustrative Embodiment (23) is the electric current sensor as described in Illustrative Embodiment (22), wherein the magnetic flux detection point is located at a center of the gap in a direction of a gap length of the gap.

According to at least one illustrative embodiment of the present invention, it may be possible to determine a positional relationship between a conducting wire and a core with increased precision more readily.

Although the illustrative embodiments and specific examples of the present invention have been described with reference to the accompanying drawings, the present invention is not limited to any of the illustrative embodiments and specific examples and the illustrative embodiments and specific examples may be altered, modified, or combined without departing from the scope of the present invention.

The present application claims the benefit of priority based on Japanese Patent Application No. 2012-104958 filed on May 1, 2012 and Japanese Patent Application No. 2013-004289 filed on Jan. 15, 2013, the entire contents of which are hereby incorporated by reference herein.

What is claimed is:

1. An electric current sensor, comprising:
a conducting wire;
a core having a hole portion mating with the conducting wire and a gap communicating with the hole portion; and
a magnetic sensor having a magnetic flux detection part arranged in the gap.

2. The electric current sensor as claimed in claim 1, further comprising:
a supporting member configured to support the magnetic flux detection part.

3. The electric current sensor as claimed in claim 2, wherein the supporting member has a core supporting part configured to support the core.

4. The electric current sensor as claimed in claim 3, wherein the core has a pair of extending parts opposed to form the gap and the core supporting part has an extending part holding part configured to hold the pair of extending parts.

5. The electric current sensor as claimed in claim 4, wherein the extending part holding part has a box part configured to hold one extending part of the pair of extending parts.

6. The electric current sensor as claimed in claim 5, wherein the extending part holding part has a wall part configured to interpose and hold an extending part other than the one extending part among the pair of extending parts.

7. The electric current sensor as claimed in claim 4, wherein the extending part holding part has a protrusion part configured to press and hold the core.

8. The electric current sensor as claimed in claim 2, wherein the supporting member has a conducting wire supporting part configured to support the conducting wire.

9. The electric current sensor as claimed in claim 8, wherein the conducting wire supporting part has a mating site supporting part configured to support a conducting wire site mating with the hole portion.

10. The electric current sensor as claimed in claim 9, wherein the mating site supporting part is arranged in the gap.

11. The electric current sensor as claims in claim 9, wherein the mating site supporting part has a magnetic flux detection part holding part configured to hold the magnetic flux detection part.

12. The electric current sensor as claimed in claim 11, wherein the magnetic flux detection part holding part has a claw part configured to lock the magnetic flux detection part.

13. The electric current sensor as claimed in claim 1, wherein the conducting wire is rotatable with respect to the core.

14. The electric current sensor as claimed in claim 1, wherein the core is made from an oriented magnetic steel sheet.

15. The electric current sensor as claimed in claim 14, wherein the core has a pair of extending parts opposed to form the gap and the core is configured in such a manner that a direction of extension of the extending parts coincides with a direction of rolling of the oriented magnetic steel sheet.

16. The electric current sensor as claimed in claim 1, further comprising:
an insulating cover part configured to cover the core.

17. The electric current sensor as claimed in claim 16, wherein the cover part is formed by powder coating.

18. The electric current sensor as claimed in claim 1, wherein the magnetic flux detection part has a magnetic flux detection point located at a side of the hole portion with respect to a position of a center of the gap in a direction of communication between the hole portion and the gap.

19. The electric current sensor as claimed in claim 18, wherein the magnetic flux detection point is located at a center of the gap in a direction of a gap length of the gap.
